(19) United States
(12) Patent Application Publication
(10) Pub. No.: US 2019/0218101 A1
(43) Pub. Date: Jul. 18, 2019

(54) GRAPHENE THERMAL PASTE AND MANUFACTURING METHOD THEREOF

(71) Applicant: TUNGNAN UNIVERSITY, New Taipei City (TW)

(72) Inventors: Jen-Ching Huang, Taipei City (TW); Chih-Wei Wang, New Taipei City (TW)

(21) Appl. No.: 15/871,111

(22) Filed: Jan. 15, 2018

(51) Int. Cl. C01B 32/194; H05K 1/02; C08L 83/04

(52) U.S. Cl. CPC C01B 32/194; H05K 1/0201; H01L 21/441; C01B 2204/24; C08L 83/04

(57) ABSTRACT

The present invention provides a graphene thermal paste and the manufacturing method thereof, wherein the thermal paste mainly serves as a thermal interface material between the semiconductor element and the cooling device. The manufacturing method of the present invention includes the following processes: (a) A graphene is mixed with a grease carrier to make a graphene oil; (b) The graphene oil is mixed with a dispersant to make a mixture of the dispersant and the graphene oil; and (c) The mixture is heated to volatilize the dispersant to make the thermal paste; wherein the manufactured thermal paste contains 5 to 35 wt % of graphene. In addition, the present invention also provides the test results of the graphene thermal paste manufactured by the above method. Through the experimental testing, the graphene thermal paste of the present invention has more excellent thermal conduction performance than the commercially available thermal paste.

### TECHNICAL FIELD OF THE INVENTION

The present invention is related to a thermal interface material, and especially related to a thermal paste containing the graphene and the olive oil as the main components.

### DESCRIPTION OF THE PRIOR ART

In general, the heat dissipation strategy used in electronic products is to contact the semiconductor components with the heat sink or the chassis so as to conduct the heat to a cooling device or the chassis. The conventional cooling device usually has a plurality of cooling fins. To further improve the heat dissipation performance, some of the cooling devices are further attached to a fan, a heat pipe or the water-cooled system.

However, due to the tiny defects on the contact surface, the actual contact area between two surfaces will be much smaller than the total area of the contact surface. The gap between two surfaces is filled with air which has the high thermal resistance, so that the heat generated by the semiconductor components cannot be efficiently conducted to the cooling device or the chassis.

In order to solve the above problem, a thermal interface material is generally coated or provided on the contact surface. The thermal interface material can fill in the tiny defects on the contact surface and significantly increase the effective heat dissipation area between two surfaces to reduce the thermal impedance.

The thermal paste is one of the most widely used thermal interface materials. A good thermal interface material must have the characteristics of low thermal resistance, high thermal conduction coefficient, and insulation.

Most commercial thermal paste use insulation materials such as: epoxy resin, silicone oil or paraffin oil as a carrier, adding the powder of high thermal conduction, such as: metal powder, metal oxide powder or carbon compound powder to enhance the thermal conduction properties.

However, the thermal paste made using the above materials is limited in the thermal conduction properties such as the thermal conduction coefficient and the thermal resistance. Therefore, it is necessary to develop a thermal paste using a novel powder with high thermal conduction to meet the demand of high heat dissipation efficiency of the electronic products today.

### SUMMARY OF THE INVENTION

To solve the above shortcomings of the prior art, the present invention provides a graphene thermal paste and the manufacturing method thereof to overcome the limitation of the thermal conduction property of a conventional thermal paste.

To achieve the above and other objects, the present invention provides a method for manufacturing a thermal paste, including the following processes:

(a) a graphene is mixed with a grease carrier to make a graphene oil;

(b) The graphene oil is mixed with a dispersant to make a mixture of the dispersant and the graphene oil; and

(c) The mixture is heated to volatilize the dispersant to make the thermal paste; wherein the manufactured thermal paste contains 5 to 35 wt % of graphene.

In addition, the present invention also provides a graphene thermal paste manufactured by the above method.

The above graphene thermal paste, wherein the thermal paste preferably contains 10-35 wt % of graphene, and more preferably 20-30 wt %.

### BRIEF DESCRIPTION OF THE DRAWINGS

FIG. 1 is a flow chart of the manufacturing processes for the graphene thermal paste according to the present invention.

FIG. 2 is a diagram of the temperature change with respect to the measuring point for the 20% graphene thermal paste according to the embodiment 1 of the present invention (120 W).

FIG. 3 is a diagram of the temperature change with respect to the measuring point for the 30% graphene thermal paste according to the embodiment 2 of the present invention (120 W).

FIG. 4 is a diagram of the temperature change with respect to the measuring point for the 30% graphene thermal paste through the ultrasonic oscillation procedure according to the embodiment 3 of the present invention (120 W), wherein the thermal paste is changed to use the olive oil as the grease carrier.

FIG. 5 is a diagram of the temperature change with respect to the measuring point for the 30% graphene thermal paste through the ultrasonic oscillation procedure according to the embodiment 4 of the present invention (120 W), wherein the thermal paste is changed to use the olive oil as the grease carrier and changed to use the isopropanol as the dispersant.

FIG. 6 is a diagram of the temperature change with respect to the measuring point for commercially available thermal paste (120 W).

### DETAILED DESCRIPTION OF THE PREFERRED EMBODIMENTS

The following descriptions are exemplary embodiments only, and are not intended to limit the scope, applicability or configuration of the invention in any way. Rather, the following detailed description provides a convenient illustration for implementing exemplary embodiments of the invention. Various changes to the described embodiments may be made in the function and arrangement of the elements described without departing from the scope of the invention as set forth in the appended claims.

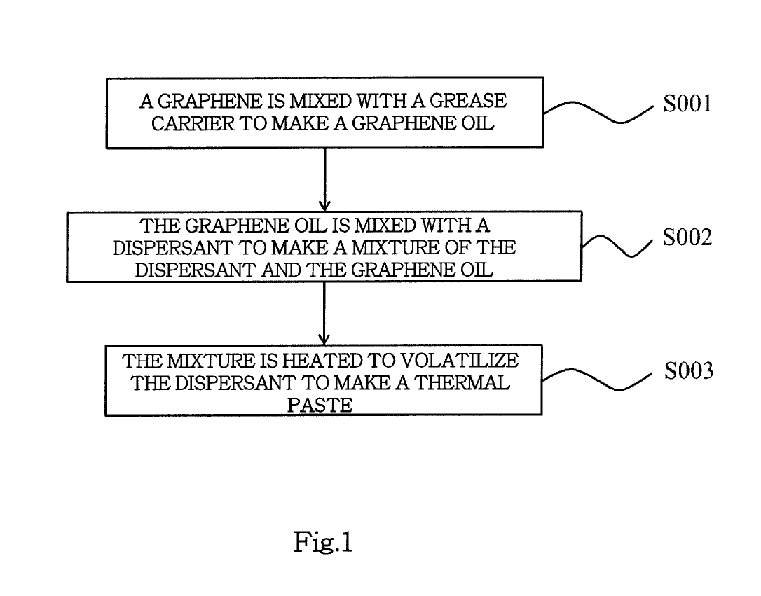

The graphene thermal paste manufacturing processes of the present invention are described in the following and shown in FIG. 1.

(a) A graphene is mixed with a grease carrier to make a graphene oil (S001).

In the graphene thermal paste of the present invention, the grease carrier can be simply silicon oil or olive oil, or a mixture oil of the silicone oil and the olive oil. The mixing ratio is preferably 40-60 wt % of the silicone oil, and 60-40 wt % of the olive oil.

(b) The graphene oil (S001) is mixed with a dispersant to make a mixture of the dispersant and the graphene oil, wherein the dispersant can use any liquid that can prevent the powder from settling and agglomerating. For removing the dispersant effectively in the subsequent heating process, the dispersant must also have the property of easy volatility.

In the aforementioned graphene liquid, the weight ratio of graphene to the dispersant is not particularly limited as long as the graphene can be well dispersed in the dispersant, preferably 1:0.5 to 1:2.

In the above step (a) And step (b), an ultrasonic oscillation procedure may further be included which uses the ultrasonic oscillation for the graphene oil obtained in step (a) And the graphene mixture obtained in step (b) to ensure that the graphene is well dispersed in the thermal paste to further enhance the thermal conduction performance. The time duration for performing the ultrasonic oscillation procedure may be adjusted according to the mixing situation of the graphene and the grease carrier, preferably 0.5 to 2 hours.

In embodiments 1 to 4, the ultrasonic oscillation procedure is performed in both step (a) And step (b), but may also be adjusted appropriately to perform only in step (a) or step (b) process according to the mixing situation.

(c) The mixture is heated to volatilize the dispersant to make a thermal paste (S003). In the present invention, the mixture may be heated using any conventional heating means (e.g., electrothermal platform), and the time duration for heating the mixture may be adjusted according to the thickness of the mixture. Wherein, the manufactured thermal paste contains 5 to 35 wt % of graphene.

The recipe and the configuration conditions of the graphene thermal paste for embodiments 1 to 4 are shown in Table 1. The wt % of graphene in Table 1 represents the weight percent of graphene in the thermal paste made by the above method.

TABLE 1

| | | | | Time | Time |
|---|---|---|---|---|---|
| | | | | Duration | Duration |
| | | | | of | of |
| | | | | Ultrasonic | Heating |
| | graphene | | Grease | Oscillation | Mixture |
| | (wt %) | Dispersant | Carrier | (hour) | (hour) |
| Embodiment | 20 | Ethanol | Silicone | 1 | 1.5 |
| 1 | | | Oil | | |
| Embodiment | 30 | Ethanol | Silicone | 1 | 1.5 |
| 2 | | | Oil | | |
| Embodiment | 30 | Ethanol | Olive | 1 | 1.5 |
| 3 | | | Oil | | |
| Embodiment | 30 | Isopropanol | Olive | 1 | 1.5 |
| 4 | | | Oil | | |

In order to understand the thermal conduction characteristics of the graphene thermal paste of the present invention at different temperatures, the coefficients of the thermal impedance and the thermal conduction of above-mentioned embodiments 1 to 4 are measured according to the standard ASTM D5470 set by the American Society for Testing and Materials (ASTM), and which of the thermal paste commercially available are simultaneously measured to compare.

In order to understand the thermal conduction characteristics of the graphene thermal paste of the present invention at different temperatures, the coefficients of the thermal impedance and the thermal conduction of above-mentioned embodiments 1 to 4 are measured according to the standard ASTM D5470 set by the American Society for Testing and Materials (ASTM), and which of the thermal paste commercially available are simultaneously measured to compare.

The test apparatuses used in the following experiments have a heater capable of controlling the heating power to conduct the heat at a specific heating power to a first metal cuboid having a length and width of 40 mm and a height of 55 mm. One end of the first metal cuboid is connected with the heater, and the other end of the first metal cuboid is coated with the thermal interface material. The thickness of the thermal interface material to be tested is about 0.03-0.05 mm. One end surface of another metal cuboid, the second metal cuboid, with the same size is in contact with the thermal interface material to be tested.

The temperature sensors are respectively set at a distance of 0, 25 and 50 mm from the contact surface between the heater and the contact surface of the first metal cuboid, and between the second cuboid and the thermal interface material to be tested at a distance of 5, 30 and 55 mm, the measured temperature values are T1, T2, T3, T4, T5 and T6.

The aforementioned apparatuses are covered with a thermal insulation material to prevent the heat from being dissipated. The test instrument also has a cooling fan for controlling the system temperature. The coefficients of the thermal impedance and the thermal conduction of various thermal interface materials are measured at different heating powers at about 120 W heating power.

The 20% graphene thermal paste of embodiment 1 is measured at a heating power of about 120 W, the calculation results are shown in Table 2, and in Table 2, the ΔTA, ΔTB, ΔTC, and ΔTD are the temperature difference between two measuring points 25 mm away from each other.

TABLE 2

| | T1 | T2 | T3 | T4 | T5 | T6 |
|---|---|---|---|---|---|---|
| Temperature | 84.7 | 82.2 | 79.58 | 78.15 | 75.6 | 73.2 |
| ° C. | | | | | | |

ΔTA = T1 − T2 = 2.5
ΔTB = T2 − T3 = 2.62
ΔTC = T4 − T5 = 2.55
ΔTD = T5 − T6 = 2.4

According to the measurement results in Table 2, the calculation results are summarized in Table 3, where R represents the thermal impedance, K represents the thermal conduction coefficient, and ΔT represents the average temperature difference between the measuring points with two 25 mm spacing, which the ΔTA, ΔTB, ΔTC, and ΔTD are based on the calculation result of ΔT.

| | T1 | T2 | T3 | T4 | T5 | T6 |
|---|---|---|---|---|---|---|
| Temperature | 84.7 | 82.2 | 79.58 | 78.15 | 75.6 | 73.2 |
| ° C. | | | | | | |

ΔTA = T1 − T2 = 2.5
ΔTB = T2 − T3 = 2.62
ΔTC = T4 − T5 = 2.55
ΔTD = T5 − T6 = 2.4

According to the measurement results in Table 2, the calculation results are summarized in Table 3, where R represents the thermal impedance, K represents the thermal conduction coefficient, and ΔT represents the average temperature difference between the measuring points with two 25 mm spacing, which the ΔTA, ΔTB, ΔTC, and ΔTD are based on the calculation result of ΔT.

Assuming a linear relationship between the temperature and the measuring point in the metal cuboid, it can be inferred that the temperature difference between the measuring points with a distance of 5 mm is ΔT1 (ΔT1=ΔT×5/25). The distance between the end face of the first metal cuboid in contact with the thermal paste and the measuring point T3 is 5 mm, so that the first interface temperature Ta of the end surface can be inferred as T3 -ΔT1.

Similarly, the end surface of the second metal cuboid in contact with the thermal conductive paste is also 5 mm away from the measuring point T4, so that it can be also inferred that the second interface temperature Tb is T4+ΔT1. The thermal resistance value R is the temperature difference (Ta-Tb) between two interfaces divided by the heating power (W).

The thermal conduction coefficient K is in units of W/m·° C., where W is the heating power, m=A/L, A is the cross-sectional area of the thermal interface material, L is thickness of the thermal interface material, ° C. is the temperature difference between two interfaces.

In the case of the same heating power and the same cross-sectional area and thickness of the thermal interface material, the temperature difference between two interfaces is inversely proportional to the thermal conduction coefficient. Based on a commercially available thermal paste having a thermal conduction coefficient of 0.9 W/m·° C. and according to the relationship of K_{0.9}:Kₜₑₛₜ=1/° C._{0.9}:1/° C.ₜₑₛₜ to calculate the thermal conduction coefficients of the graphene thermal paste and the silicone oil of the present invention.

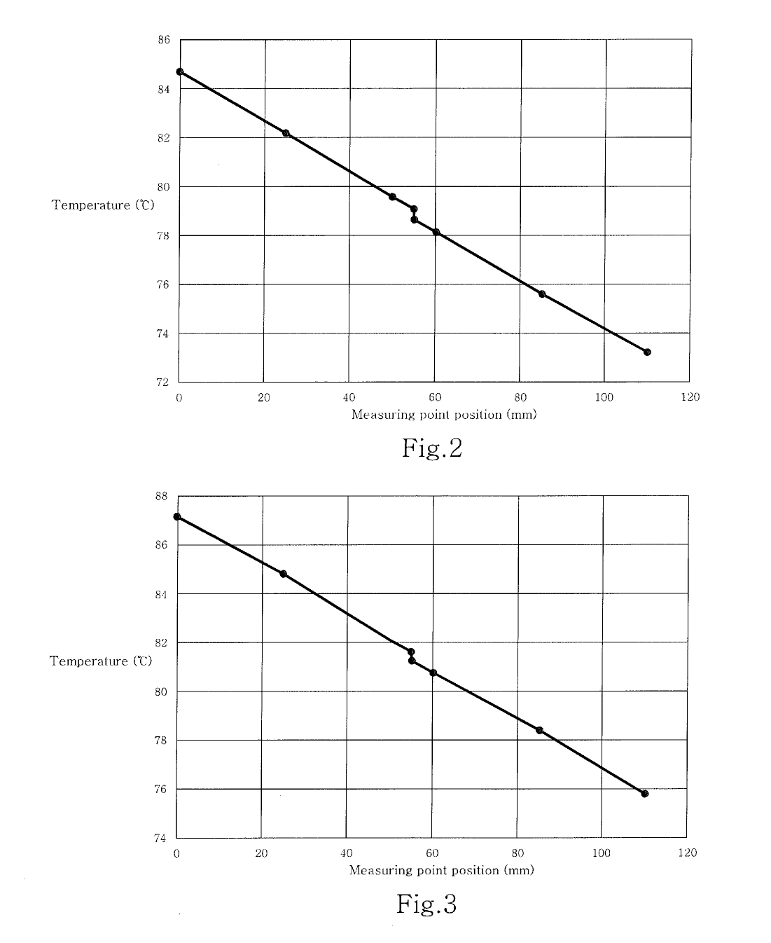

In addition, based on the measurements and calculations in Tables 2 and 3, the measurement locations of T1, T2, T3, Ta, Tb, T4, T5 and T6 are 0, 25, 50, 55, 55.1, 60.1, 85.1 and 110.1 respectively. FIG. 2 is a diagram of the temperature change with respect to the measuring point, where the measuring point position is the X axis, the temperature is the Y axis. And, the following groups of experimental data, diagrams, and tables are all calculated and drawn in accordance with the above method.

TABLE 3

| ΔT | ΔT₁ | Ta | Tb | R | Ta − Tb | K |
|---|---|---|---|---|---|---|
| (° C.) | (° C.) | (° C.) | (° C.) | (° C./W) | (° C.) | (W/m · ° C.) |
| 2.5175 | 0.5035 | 79.0765 | 78.654 | 0.00364 | 0.4230 | 5.57 |

Heating Power: 116.47 W

TABLE 4

| | T1 | T2 | T3 | T4 | T5 | T6 |
|---|---|---|---|---|---|---|
| Temperature ° C. | 87.15 | 84.8 | 82.11 | 80.75 | 78.4 | 75.8 |

ΔTA = T1 − T2 = 2.35
ΔTB = T2 − T3 = 2.69
ΔTC = T4 − T5 = 2.35
ΔTD = T5 − T6 = 2.6

TABLE 5

| ΔT | ΔT₁ | Ta | Tb | R | Ta − Tb | |
|---|---|---|---|---|---|---|
| (° C.) | (° C.) | (° C.) | (° C.) | (° C./W) | (° C.) | K (W/m · ° C.) |
| 2.4975 | 0.4995 | 81.6105 | 81.25 | 0.00303 | 0.3610 | 6.53 |

Heating Power: 119.20 W

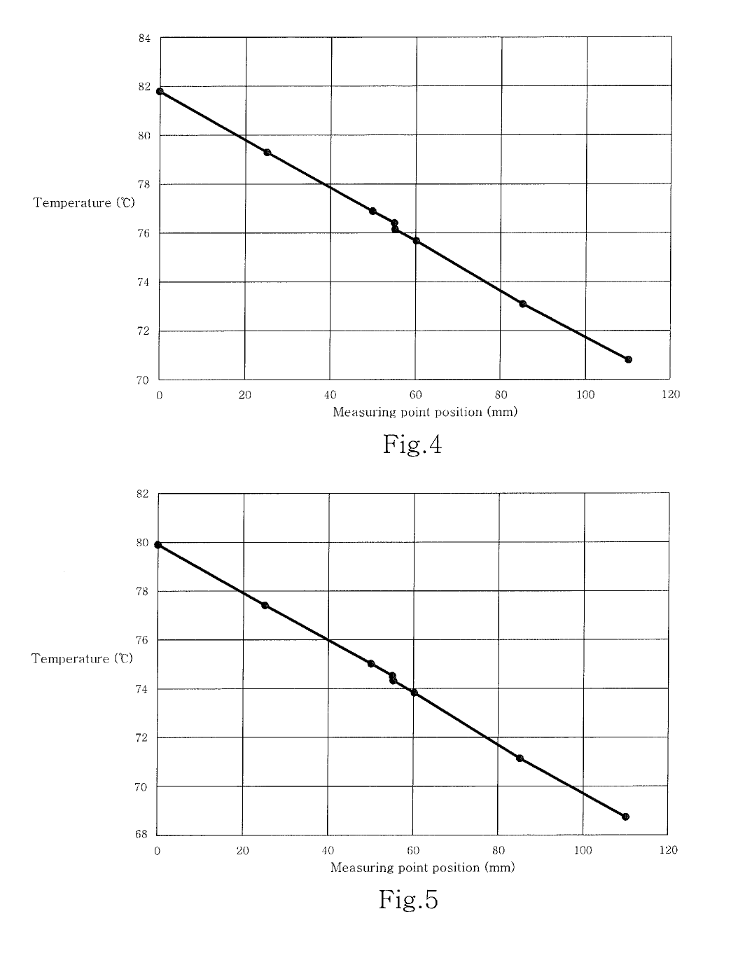

The embodiment 3 uses the olive oil as the grease carrier and the ethanol as the dispersant, which the 30% graphene thermal paste is obtained through the ultrasonic oscillation procedure. The thermal paste is measured at about 120 W heating power, which the calculation results are shown in Table 6 and Table 7, and the temperature change with respect to the measuring point is shown in FIG. 4.

TABLE 6

| | T1 | T2 | T3 | T4 | T5 | T6 |
|---|---|---|---|---|---|---|
| Temperature ° C. | 81.8 | 79.3 | 76.9 | 75.67 | 73.1 | 70.8 |

ΔTA = T1 − T2 = 2.5
ΔTB = T2 − T3 = 2.4
ΔTC = T4 − T5 = 2.57
ΔTD = T5 − T6 = 2.3

TABLE 7

| ΔT | ΔT₁ | Ta | Tb | R | Ta − Tb | K |
|---|---|---|---|---|---|---|
| (° C.) | (° C.) | (° C.) | (° C.) | (° C./W) | (° C.) | (W/m · ° C.) |
| 2.4425 | 0.4885 | 76.4115 | 76.159 | 0.00212 | 0.2530 | 9.32 |

Heating Power: 115.68 W

The embodiment 4 uses the olive oil as the grease carrier and the isopropanol as the dispersant, which the 30% graphene thermal paste is obtained through the ultrasonic oscillation procedure. The thermal paste is measured at about 120 W heating power, which the calculation results are shown in Table 8 and Table 9, and the temperature change with respect to the measuring point is shown in FIG. 5.

TABLE 8

| | T1 | T2 | T3 | T4 | T5 | T6 |
|---|---|---|---|---|---|---|
| Temperature ° C. | 79.9 | 77.4 | 75 | 73.8 | 71.1 | 68.7 |

ΔTA = T1 − T2 = 2.5
ΔTB = T2 − T3 = 2.4
ΔTC = T4 − T5 = 2.7
ΔTD = T5 − T6 = 2.4

TABLE 9

| ΔT | ΔT₁ | Ta | Tb | R | | |
|---|---|---|---|---|---|---|
| (° C.) | (° C.) | (° C.) | (° C.) | (° C./W) | Ta − Tb (° C.) | K (W/m · ° C.) |
| 2.5 | 0.5 | 74.5 | 74.3 | 0.00168 | 0.2000 | 11.79 |

Heating Power: 118.12 W

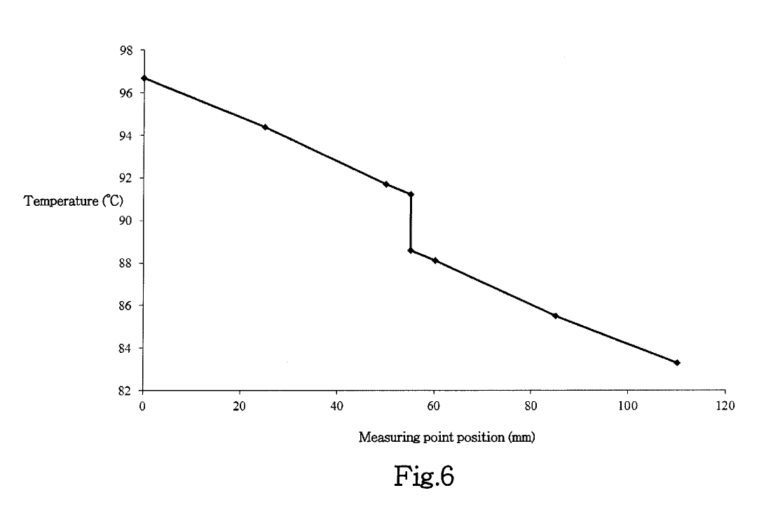

The measurement of the commercially available thermal paste at a heating power of about 120 W is shown in Table 10 and Table 11, and the temperature change with respect to the measuring point is shown in FIG. 6.

TABLE 10

| | | | | | | |
|---|---|---|---|---|---|---|
| Temperature ° C. | 96.7 | 94.4 | 91.7 | 88.1 | 85.5 | 83.3 |

ΔTA = T1 − T2 = 2.3
ΔTB = T2 − T3 = 2.7
ΔTC = T4 − T5 = 2.6
ΔTD = T5 − T6 = 2.2

TABLE 11

| ΔT | ΔT₁ | Ta | Tb | R | | |
|---|---|---|---|---|---|---|
| (° C.) | (° C.) | (° C.) | (° C.) | (° C./W) | Ta − Tb (° C.) | K (W/m · ° C.) |
| 2.45 | 0.49 | 91.21 | 88.59 | 0.02316 | 2.6200 | 0.9 |

Heating Power: 113.142 W

To summarize the measurement of the coefficients of the thermal impedance and the thermal conduction for above 5 groups of tested thermal interface materials, the results are shown in Table 12 for comparison.

TABLE 12

| | graphene content | R(° C./W) | K(W/m · ° C.) |
|---|---|---|---|
| Embodiment 1 | 20% | 0.00364 | 5.57 |
| | (Ethanol, | | |
| | Silicone Oil) | | |
| Embodiment 2 | 30% | 0.00303 | 6.53 |
| | (Ethanol, | | |
| | Silicone Oil) | | |
| Embodiment 3 | 30% | 0.00212 | 9.32 |
| | (Ethanol, | | |
| | Olive Oil) | | |
| Embodiment 4 | 30% | 0.00168 | 11.79 |
| | (Isopropanol, | | |
| | Olive Oil) | | |
| Commercially | None | 0.02316 | 0.9 |
| Available | | | |
| Thermal Paste | | | |

Test Condition: Heating Power [symbol] 120 W

Considering the thermal interface material, the lower thermal resistance and higher thermal conduction coefficient will help to improve the heat dissipation efficiency.

From the results of Table 12, it can be seen that the graphene thermal paste of the present invention has a thermal resistance of 0.00364 to 0.00168° C./W in the case of graphene with a content of 20˜30% and a thermal conduction coefficient of ranging from 5.57 to 11.79 W/m·° C., which are both significantly better than 0.02316° C./W and 0.9 W/m˜° C. for the commercially available thermal paste.

Among them, the 30% graphene thermal paste of the embodiment 4 which uses the isopropanol as the dispersant and the olive oil as the grease carrier oil is the best.

To summarize the measurements, the graphene thermal paste of the present invention has advantages over the commercially available thermal paste based on the above measurements and calculation data.

Among them, graphene can be well dispersed in the grease carrier after the ultrasonic oscillation to further reduce the thermal impedance of the graphene thermal paste, and so as to further enhance the thermal conduction coefficient of the graphene thermal paste.

1. A manufacturing method for a thermal paste, comprising the following processes:
(a) A graphene is mixed with a grease carrier to make a graphene oil;
(b) The graphene oil is mixed with a dispersant to make a mixture of the dispersant and the graphene oil; and
(c) The mixture is heated to volatilize the dispersant to make the thermal paste; wherein the manufactured thermal paste contains 5 to 35 wt % of graphene.

2. The manufacturing method for a thermal paste according to claim 1; wherein at least one of the processes (a) and (b) further comprises an ultrasonic oscillation procedure.

3. The manufacturing method for a thermal paste according to claim 2; wherein the time duration for performing the ultrasonic oscillation procedure is 0.5 to 2 hours.

4. The manufacturing method for a thermal paste according to claim 1; wherein the time duration for heating the mixture is 1 to 2 hours.

5. The manufacturing method for a thermal paste according to claim 1; wherein the grease carrier is silicon oil or olive oil.

6. The manufacturing method for a thermal paste according to claim 1; wherein the grease carrier is a mixture oil of the silicone oil and the olive oil.

7. The manufacturing method for a thermal paste according to claim 6; wherein the content of the silicone oil is 40˜60 wt % of the grease carrier.

8. A graphene thermal paste made by a method as claim 1.

9. The graphene thermal paste according to claim 8; wherein the thermal paste contains 5 to 35 wt % of graphene.

10. The graphene thermal paste according to claim 9; wherein the thermal paste contains 20˜30 wt % of graphene.
